(19) United States
(12) Patent Application Publication
(10) Pub. No.: US 2022/0392790 A1
(43) Pub. Date: Dec. 8, 2022

(54) SUBSTRATE PROCESSING APPARATUS AND SPRAY MODULE OF SUBSTRATE PROCESSING APPARATUS

(71) Applicant: JUSUNG ENGINEERING CO., LTD., Gwangju-si, Gyeonggi-do (KR)

(72) Inventors: InWoo BACK, Gwangju-si, Gyeonggi-do (KR); JongChul KIM, Gwangju-si, Gyeonggi-do (KR); YeongSeop BYEON, Gwangju-si, Gyeonggi-do (KR); InCheol YEO, Gwangju-si, Gyeonggi-do (KR)

(21) Appl. No.: 17/793,380

(22) PCT Filed: Jan. 22, 2021
(86) PCT No.: PCT/KR2021/000875

§ 371 Date: Jul. 15, 2022

(30) Foreign Application Priority Data
Jan. 23, 2020 (KR) 10-2020-0009353

(51) Int. Cl. H01L 21/67; H01L 21/687; C23C 16/458; C23C 16/44; C23C 16/52

(52) U.S. Cl. CPC H01L 21/67248; H01L 21/67017; H01L 21/68764; H01L 21/68771; C23C 16/4584; C23C 16/4408; C23C 16/52

(57) ABSTRACT

The present inventive concept relates to a substrate processing apparatus and a spray module of the substrate processing apparatus, the substrate processing apparatus comprising: a chamber for providing a processing space; a lid for covering the upper portion of the chamber; a substrate support portion which supports at least one substrate and rotates about a rotary shaft; a gas spray portion which is above the substrate support portion in a diameter direction from the rotary shaft of the substrate support portion and which sprays a processing gas; and a measuring portion which is arranged to be in parallel with or to be inclined in a direction at a certain angle with respect to the diameter direction on a measurement position that is spaced apart from the diameter direction and which measures the temperature of the substrate supported by the substrate support portion or the temperature of the substrate support portion.

### TECHNICAL FIELD

The present disclosure relates to a substrate processing apparatus which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc. Such a processing process is performed on a substrate by a substrate processing apparatus.

A substrate processing apparatus according to the related art includes a substrate supporting unit and a gas injecting unit which injects a processing gas toward the substrate supporting unit. The substrate supporting unit rotates about a rotation shaft. As the substrate supporting unit rotates about the rotation shaft, a substrate supported by the substrate supporting unit passes through a region under the gas injecting unit. In this process, a processing process is performed on the substrate by using a processing gas injected by the gas injecting unit.

In such a processing process, a temperature of the substrate acts as a significant factor. In order to reflect the temperature of the substrate in the processing process, the related art obtains a temperature distribution of the substrate by using thermocouple (TC) wafer before performing the processing process.

The substrate processing apparatus according to the related art may not obtain the temperature distribution of the substrate while the processing process is being performed, and thus, performs the processing process by predicting the temperature distribution of the substrate by using the temperature distribution of the substrate which is obtained before performing the processing process. However, due to a number of variables occurring in the middle of performing the processing process, a considerable difference between the predicted temperature distribution of the substrate and a real temperature distribution of the substrate occurs inevitably when the processing process is being performed. Due to such a difference, the substrate processing apparatus according to the related art has a problem where it is difficult to secure the uniformity of quality of a substrate on which the processing process is completed.

### DISCLOSURE

### Technical Problem

The present inventive concept is devised to solve the above-described problem and is for providing a substrate processing apparatuses and an injecting module thereof, which may enhance the uniformity of quality of a substrate on which a processing process is completed.

### Technical Solution

To accomplish the above-described object, the present inventive concept may include the following elements.

An apparatus for processing substrate according to the present inventive concept may include: a chamber providing a processing space; a lid covering an upper portion of the chamber; a substrate supporting unit supporting at least one substrate and rotating about a rotation shaft; a gas injecting unit disposed over a diameter direction with respect to the rotation shaft of the substrate supporting unit to inject a processing gas; and a measurement unit measuring a temperature of a substrate supported by the substrate supporting unit or a temperature of the substrate supporting unit at a measurement position apart from the diameter direction. The measurement unit is disposed in parallel with the diameter direction or disposed to be inclined in a direction having a certain angle with respect to the diameter direction.

An injecting module of an apparatus for processing substrate according to the present inventive concept may include: an injecting hole for injecting a processing gas into a chamber where a processing process is performed on a substrate; an injecting body where the injecting hole is formed in plurality; and a measurement hole formed to pass through the injecting body at a position apart from the plurality of injecting holes. Some injecting holes among the plurality of injecting holes may be disposed in parallel along a diameter direction with respect to a rotation shaft of a substrate supporting unit, the substrate supporting unit supports a substrate and rotates in the chamber. The measurement hole is disposed to be apart from injecting holes disposed in parallel along the diameter direction. The measurement hole is disposed in parallel with the diameter direction or disposed to be inclined in a direction having a certain angle with respect to the diameter direction.

### Advantageous Effect

According to the present inventive concept, the following effects may be obtained.

The present inventive concept is implemented to measure a temperature of a substrate or a temperature of a substrate supporting unit while a processing process is being performed on the substrate. Accordingly, the present inventive concept may enhance the uniformity of quality of a substrate on which the processing process is completed.

The present inventive concept is implemented so that a gas injecting unit maintains a state where the gas injecting unit is disposed in a diameter direction and a measurement unit measures a temperature of a substrate or a temperature of a substrate supporting unit at a measurement position at which interference with the gas injecting unit is reduced. Therefore, the present inventive concept may measure the temperature of the substrate or the temperature of the substrate supporting unit by using the measuring unit disposed at the measurement position and thus may obtain a temperature distribution of the substrate while a processing process is being performed, and moreover, may secure the stability of the processing process performed on the substrate by using the gas injecting unit disposed in the diameter direction.

### DESCRIPTION OF DRAWINGS

FIG. 1 is a schematic side cross-sectional view of a substrate processing apparatus according to the present inventive concept.

FIGS. 2 and 3 are schematic plan views illustrating an embodiment of a gas injecting unit in a substrate processing apparatus according to the present inventive concept.

FIG. 4 is a schematic plan view illustrating a process of measuring a temperature of a substrate through a measurement hole in a substrate processing apparatus according to the present inventive concept.

FIGS. 5 to 8 are schematic plan views illustrating an embodiment of a measurement position, at which a measurement unit is disposed, in a substrate processing apparatus according to the present inventive concept.

FIGS. 9 and 10 are schematic plan cross-sectional views illustrating an embodiment where a measurement hole is formed in a gas injecting unit in a substrate processing apparatus according to the present inventive concept.

FIG. 11 is a schematic block diagram of a substrate processing apparatus according to the present inventive concept.

FIG. 12 is a conceptual diagram for describing elements used for a conversion module to convert a noncircular detection image into a circular detection image in a substrate processing apparatus according to the present inventive concept.

FIG. 13 is a diagram illustrating an example of a noncircular detection image.

FIG. 14 is a diagram illustrating an example of a circular detection image.

### MODE FOR INVENTION

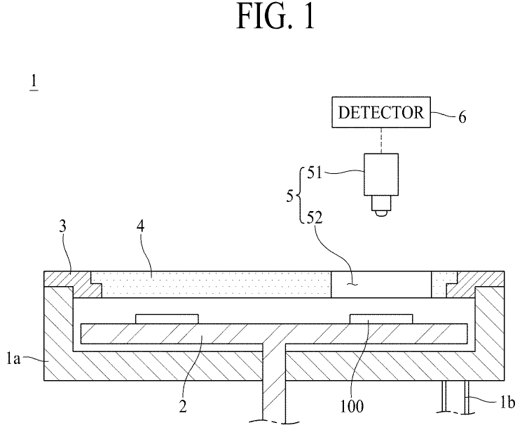

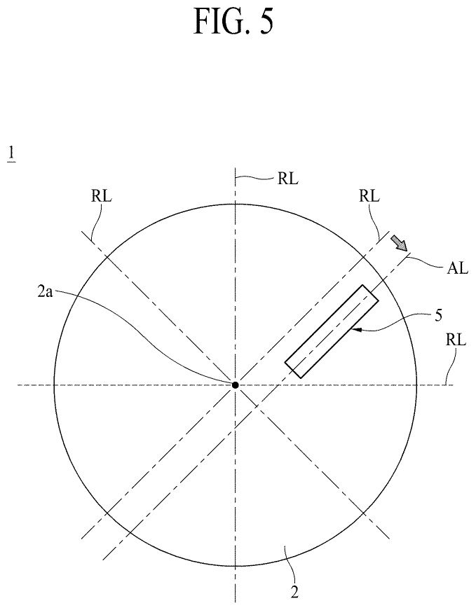

Hereinafter, an embodiment of a substrate processing apparatus according to the present inventive concept will be described in detail with reference to the accompanying drawings. An injecting module of a substrate processing apparatus according to the present inventive concept may be included in a substrate processing apparatus according to the present inventive concept, and thus, will be described in conjunction with describing an embodiment of a substrate processing apparatus according to the present inventive concept. FIG. 1 is a side cross-sectional view illustrated by using a measurement line, illustrated in FIGS. 5 to 8, as a cross-sectional line.

Referring to FIG. 1, a substrate processing apparatus 1 according to the present inventive concept performs a processing process on a substrate 100. The substrate 100 may be a glass substrate, a silicon substrate, a metal substrate, or the like. The substrate processing apparatus 1 according to the present inventive concept may perform a processing process such as a deposition process of depositing a thin film on the substrate 100 and an etching process of removing a portion of the thin film deposited on the substrate 100. Hereinafter, an embodiment where the substrate processing apparatus 1 according to the present inventive concept performs the processing process will be mainly described, but it is obvious to those skilled in the art that an embodiment, where the substrate processing apparatus 1 according to the present inventive concept performs another processing process like the etching process, is deduced based thereon.

The substrate processing apparatus 1 according to the present inventive concept may include a substrate supporting unit 2, a lid 3, a gas injecting unit 4, and a measurement unit 5.

Referring to FIG. 1, the substrate supporting unit 2 supports the substrate 100. The substrate supporting unit 2 may be coupled to an inner portion of a chamber 1a which provides a processing space where the processing process is performed. The processing space may be disposed between the substrate supporting unit 2 and the lid 3. A substrate entrance (not shown) may be coupled to the chamber 1a. The substrates 100 may pass through substrate entrance and may be loaded into the chamber 1a by a loading apparatus (not shown). When the processing process is completed, the substrates 100 may pass through substrate entrance and may be unloaded to the outside of the chamber 1a by an unloading apparatus (not shown). An exhaust unit 1b for exhausting a gas, which is in the processing space, to the outside may be coupled to the chamber 1a.

The substrate supporting unit 2 may rotate about a rotation shaft 2a. As the substrate supporting unit 2 rotates about the rotation shaft 2a, the substrate 100 supported by the substrate supporting unit 2 may pass through a region under the gas injecting unit 4 while rotating about the rotation shaft 2a. In this process, a processing process on the substrate 100 may be performed by a processing gas injected by the gas injecting unit 4. The substrate supporting unit 2 may support at least one substrate 100. In a case where the substrate supporting unit 2 supports a plurality of substrates 100, the substrates 100 may be disposed apart from one another with respect to the rotation shaft 2a. A rotation apparatus (not shown) which provides a rotational force may be coupled to the substrate supporting unit 2.

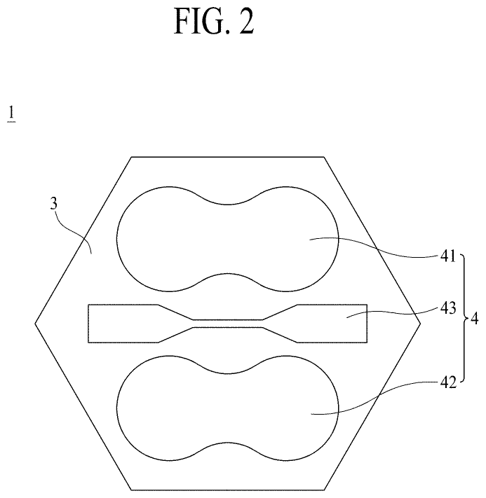

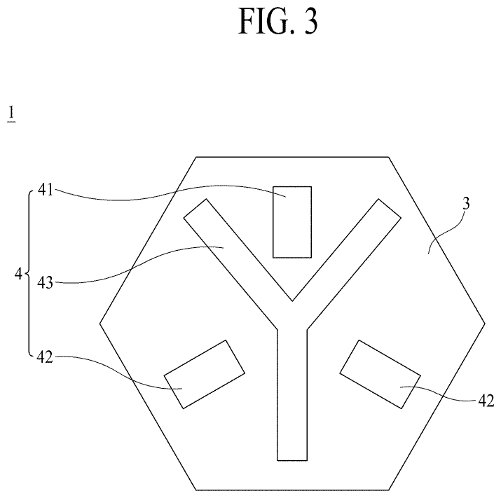

Referring to FIGS. 1 to 3, the lid 3 covers an upper portion of the chamber 1a. The lid 3 may be disposed upward apart from the substrate supporting unit 2. In FIGS. 2 and 3, the lid 3 is illustrated as being implemented in a hexagonal structure, but is not limited thereto and may be implemented in a polygonal structure such as an octagonal structure, a cylindrical structure, or an oval structure. The chamber 1a may be implemented in a shape corresponding to the lid 3.

Referring to FIGS. 1 to 3, the gas injecting unit 4 injects a processing gas toward the substrate supporting unit 2. The gas injecting unit 4 may be coupled to the lid 3. Although not shown, the gas injecting unit 4 may be coupled to the chamber 1a so as to be disposed between the lid 3 and the substrate supporting unit 2.

The gas injecting unit 4 may include a first gas injecting module 41 which injects a first gas and a second gas injecting module 42 which injects a second gas. The first gas may be a source gas, and the second gas may be a reactant gas. The first gas injecting module 41 and the second gas injecting module 42 may be disposed apart from each other with respect to the rotation shaft 2a. Therefore, when the substrate supporting unit 2 rotates about the rotation shaft 2a, the substrate 100 may sequentially pass through a region under the first gas injecting module 41 and a region under the second gas injecting module 42 while rotating about the rotation shaft 2a. Therefore, a processing process may be performed on the substrate 100 by using the first gas and the second gas. The gas injecting unit 4 may include a plurality of first gas injecting modules 41. The gas injecting unit 4 may include a plurality of second gas injecting modules 42.

The gas injecting unit 4 may include a purge gas injecting module 43 which injects a purge gas. The purge gas injecting module 43 may inject the purge gas, and thus, may divide a first region into which the first gas is injected and a second region into which the second gas is injected. Therefore, the purge gas injecting module 43 may prevent the first gas and the second gas from being mixed between the first region and the second region. When the substrate supporting unit 2 rotates about the rotation shaft 2a, the substrate 100 may pass through a region under the purge gas injecting module 43 while rotating about the rotation shaft 2a. In this process, a residual gas remaining on the substrate 100 may be purged by the purge gas. As illustrated in FIG. 2, the purge gas injecting module 43 may be implemented in a dumbbell shape which crosses between the first gas injecting module 41 and the second gas injecting module 42. As illustrated in FIG. 3, the purge gas injecting module 43 may be implemented in a Y-shape. Although not shown, the pure gas injecting module 43 may be implemented in various shapes on the basis of the number of first gas injecting modules 41 and the number of second gas injecting modules 42. The gas injecting unit 4 may include a plurality of purge gas injecting modules 43.

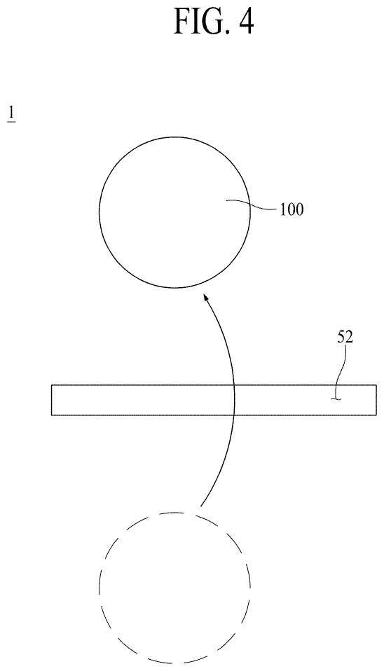

Referring to FIGS. 1 to 8, the gas injecting unit 4 may be disposed over a diameter direction with respect to the rotation shaft 2a of the substrate supporting unit 2. The diameter direction may denote a direction which passes through the rotation shaft 2a. For example, as illustrated in FIGS. 5 to 8, each of diameter lines RL passing through the rotation shaft 2a may be disposed in the diameter direction. In FIGS. 5 to 8, only four diameter lines RL extending in a radial direction with respect to the rotation shaft 2a is illustrated, but are not limited thereto and all diameter lines RL extending in the radial direction with respect to the rotation shaft 2a may be disposed in the diameter direction.

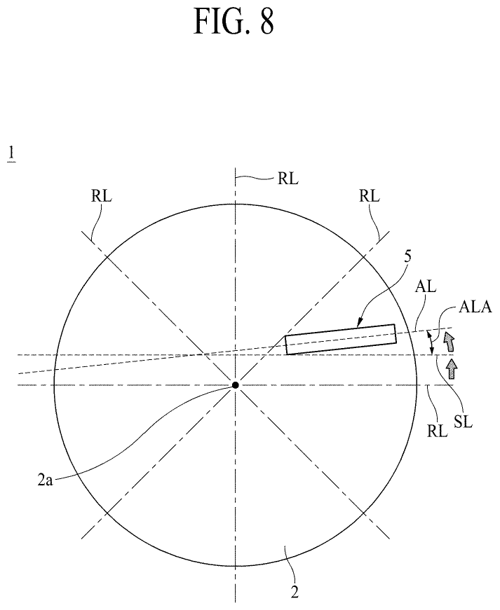

Referring to FIGS. 1 to 8, the measurement unit 5 measures a temperature of the substrate 100 supported by the substrate supporting unit 2. The measurement unit 5 may measure a temperature of the substrate supporting unit 2. In this case, the temperature of the substrate supporting unit 2 includes a temperature of a portion, uncovered by the substrate 100, of the substrate supporting unit 2 and a temperature of the substrate 100. Hereinafter, measuring the temperature of the substrate supporting unit 2 should be construed as including the temperature of the portion, uncovered by the substrate 100, of the substrate supporting unit 2 and the temperature of the substrate 100. The measurement unit 5 may be disposed at a measurement position. The measurement position is a position apart from the diameter direction and denotes a position which is disposed in parallel with the diameter direction or disposed to be inclined in a direction having a certain angle. For example, as illustrated in FIGS. 5 to 7, the measurement position may be disposed in a measurement line AL which is disposed apart from the diameter line RL and in parallel with the diameter line RL. As illustrated in FIG. 8, the measurement position may be disposed in the measurement line AL which is disposed to be apart from the diameter line RL and to be inclined in a direction having a certain angle with respect to the diameter line RL. Therefore, the substrate processing apparatus 1 according to the present inventive concept is implemented so that the gas injecting unit 4 maintains a state where the gas injecting unit 4 is disposed in the diameter direction and the measurement unit 5 measures the temperature of the substrate 100 at a measurement position at which interference with the gas injecting unit 4 is reduced. The substrate supporting unit 2 may rotate so that the substrate 100 passes through a region under the measurement unit 5 in a process where the substrate 100 rotates to pass through a region under the gas injecting unit 4. Therefore, the substrate processing apparatus 1 according to the present inventive concept may secure the stability of the processing process performed on the substrate 100 by using the gas injecting unit 4 disposed in the diameter direction, and moreover, may measure the temperature of the substrate 100 or the temperature of the substrate supporting unit 2 by using the measuring unit 5 disposed at the measurement position, thereby obtaining a temperature distribution of the substrate 100 while the processing process is being performed. Accordingly, the substrate processing apparatus 1 according to the present inventive concept may change a process condition on the basis of the temperature distribution of the substrate 100 obtained by using the measurement unit 5, thereby enhancing the uniformity of quality of a substrate 100 on which the processing process is completed.

Here, when the measurement unit 5 is disposed to be apart from the diameter direction and to be inclined in a direction having a certain angle with respect to the diameter direction, the certain angle may denote an inclined angle ALA which is inclined with respect to a separation line SL disposed to be apart from and parallel to the diameter line RL as illustrated in FIG. 8. The inclined angle ALA may be greater than 0 degrees and less than or equal to 45 degrees. In a case where the inclined angle ALA is greater than 45 degrees, a length may excessively increase so that the measurement unit 5 measures a total temperature of the substrate 100, and thus, the substrate processing apparatus 1 according to the present inventive concept may be implemented so that the inclined angle ALA is less than or equal to 45 degrees.

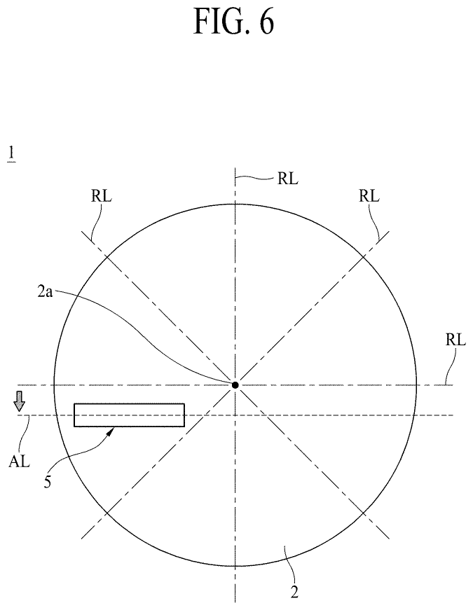

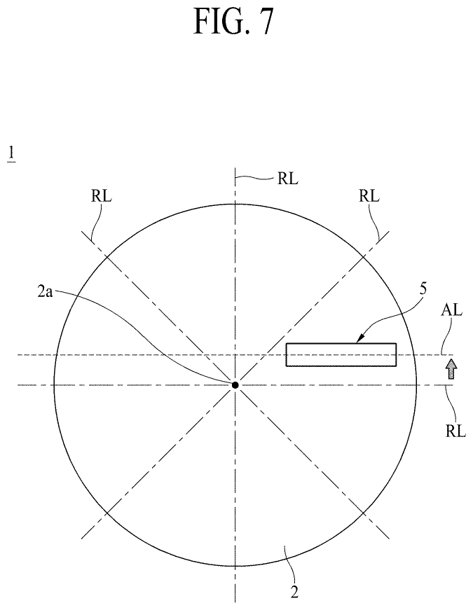

The measurement unit 5 may be disposed to be parallel to the diameter direction or to be inclined in a direction having a certain angle at a measurement position apart from one of a plurality of diameter lines RL, and thus, may measure a temperature of the substrate 100 supported by the substrate supporting unit 2 or a temperature of the substrate supporting unit 2. In FIG. 5, it is illustrated that the measurement unit 5 is disposed in a measurement line AL which is apart from a diameter line RL disposed diagonally and parallel to a corresponding diameter line RL. In FIGS. 6 and 7, it is illustrated that the measurement unit 5 is disposed in a measurement line AL which is apart from a diameter line RL disposed horizontally and parallel to a corresponding diameter line RL. In FIG. 8, it is illustrated that the measurement unit 5 is disposed in a measurement line AL which is apart from a diameter line RL disposed horizontally and is inclined by a certain angle with respect to a corresponding diameter line RL. However, the present inventive concept is not limited to such embodiments, and the measurement unit 5 may be disposed at various positions for decreasing interference with the gas injecting unit 4 and measuring the temperature of the substrate 100 or the substrate supporting unit 2. In this case, the measurement unit 5 may be disposed on a rotation path where the substrate 100 rotates based on a rotation of the substrate supporting unit 2.

The measurement unit 5 may include a measurement mechanism 51 and a measurement hole 52.

The measurement mechanism 51 measures the temperature of the substrate 100 or the temperature of the substrate supporting unit 2. The substrate supporting unit 2 may rotate with respect to the rotation shaft 2a so that the substrate 100 passes through a region under the measurement mechanism 51. Therefore, the measurement mechanism 51 may measure the temperature of the substrate 100 passing through a region under the measurement hole 52 and the temperature of the substrate supporting unit 2 passing through the region under the measurement hole 52 to obtain temperature data. In this case, the measurement mechanism 51 may sequentially obtain temperature data of portions of the substrate 100 or portions of the substrate supporting unit 2, and thus, may obtain a total temperature distribution of the substrate 100 or the substrate supporting unit 2. Accordingly, the measurement mechanism 51 may obtain the temperature distribution of the substrate 100 while the processing process is being performed. The measurement mechanism 51 may be a line scanner which measures a temperature by using an infrared ray (IR).

The measurement mechanism 51 may measure the temperature of the substrate 100 passing through the region under the measurement hole 52 and the temperature of the substrate supporting unit 2 passing through the region under the measurement hole 52. Therefore, even when the measurement mechanism 51 is disposed outside the processing space, the measurement mechanism 51 may measure, through the measurement hole 52, the temperature of the substrate 100 or the temperature of the substrate supporting unit 2, which is placed in the processing space. The measurement mechanism 51 may be disposed on the measurement hole 52.

The measurement hole 52 may be disposed at the measurement position which is apart from the diameter direction. Therefore, the measurement hole 52 may be disposed to decrease interference with the gas injecting unit 4. Because the measurement mechanism 51 is disposed on the measurement hole 52, the measurement mechanism 51 may also be disposed to decrease interference with the gas injecting unit 4.

The measurement hole 52 may be disposed in parallel with the diameter direction or disposed to be inclined in a direction having a certain angle with respect to the diameter direction, at the measurement position apart from the diameter direction. Therefore, the measurement mechanism 51 may sequentially obtain temperature data of portions of the substrate 100 or portions of the substrate supporting unit 2, which pass through a region under the measurement hole 52 via the measurement hole 52, and thus, may obtain a total temperature distribution of the substrate 100. In this case, the measurement hole 52 may be formed to have a longer length than a diameter of the substrate 100 in a direction extending in parallel with the diameter direction. That is, the measurement hole 52 may be formed along the measurement line AL to have a longer length than the diameter of the substrate 100. The measurement hole 52 may be formed to have a shorter length than the diameter of the substrate 100 with respect to a direction in which the substrate 100 rotates about the rotation shaft 2a. The measurement hole 52 may be formed in a slit shape, which is wholly tetragonal, or a long hole shape which extends in parallel with the diameter direction.

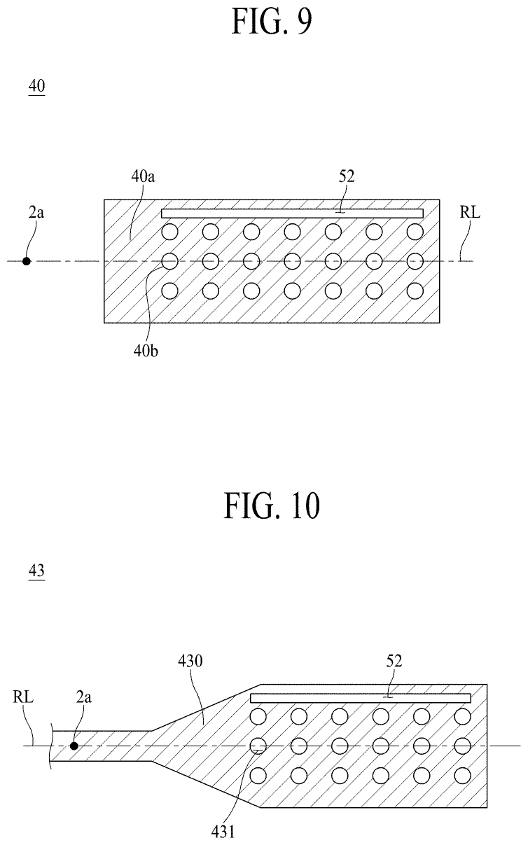

Referring to FIGS. 1 to 9, the measurement hole 52 may be formed in the gas injecting unit 4. The measurement hole 52 may be formed in at least one of injecting modules 40 (illustrated in FIG. 9) included in the gas injecting unit 4. The injecting module 40 may be at least one of the first gas injecting module 41, the second gas injecting module 42, and the purge gas injecting module 43. The injecting module 40 with the measurement hole 52 formed therein may correspond to an injecting module of the substrate processing apparatus according to the present inventive concept.

The injecting module 40 may include an injecting body 40a and a plurality of injecting holes 40b.

The injecting body 40a is disposed on the substrate supporting unit 2. The injecting body 40a may be coupled to the lid 3. The injecting body 40a may be connected to a processing gas supply unit (not shown).

The injecting holes 40b may be formed in the injecting body 40a. A processing gas supplied by the processing gas supply unit may move along an inner portion of the injecting body 40a and then may be injected toward the substrate supporting unit 2 through the injecting holes 40b. The injecting holes 40b may be disposed at positions apart from one another. Accordingly, the processing gas may be injected toward different portions of the substrate 100 through the injecting holes 40b.

In this case, the measurement hole 52 may be formed to pass through the injecting body 40a at a position apart from the injecting holes 40b. The measurement hole 52 may be disposed to be apart from the injecting holes 40b disposed in parallel along the diameter direction among the injecting holes 40b. The measurement hole 52 may be disposed in parallel with the diameter direction or disposed to be inclined in a direction having a certain angle with respect to the diameter direction. Accordingly, the measurement hole 52 is disposed to decrease interference with the injecting holes 40b and is implemented so that the measurement mechanism 51 sequentially obtains temperature data of portions of the substrate 100 or portions of the substrate supporting unit 2 to obtain a total temperature distribution of the substrate 100. The injecting holes 40b disposed in parallel along the diameter direction denotes the injecting holes 40b disposed in the diameter line RL as illustrated in FIG. 9.

The measurement hole 52 may be formed at a position which is apart from, by different distances, one side of the injecting body 40a and the other side of the injecting body 40a with respect to a direction in which the substrate 100 supported by the substrate supporting unit 2 rotates about the rotation shaft 2a. That is, the measurement hole 52 may be formed at a position close to one portion of the one side of the injecting body 40a and the other side of the injecting body 40a. Accordingly, the measurement hole 52 may be disposed to decrease interference with the injecting holes 40b. Also, the injecting holes 40b may be additionally disposed between the measurement hole 52 and the injecting holes 40b disposed in the diameter line RL.

Referring to FIGS. 1 and 10, the measurement hole 52 may be formed in the purge gas injecting module 43. In this case, comparing with a first embodiment where the measurement hole 52 is formed in the first gas injecting module 41 or the second gas injecting module 42, a second embodiment where the measurement hole 52 is formed in the purge gas injecting module 43 may more decrease an influence of the measurement hole 52 on the processing process. This is because a gas injected by the first gas injecting module 41 or the second gas injecting module 42 affects the processing process directly, but the purge gas injected by the purge gas injecting module 43 does not directly affect the processing process. For example, in a case where the first gas injecting module 41 and the second gas injecting module 42 inject the source gas and the reactant gas, the source gas and the reactant gas affect a deposition performed on the substrate 100 directly, but the purge gas injected by the purge gas injecting module 43 does not directly affect the deposition process. Accordingly, the substrate processing apparatus 1 according to the present inventive concept is implemented so that the measurement hole 52 is formed in the purge gas injecting module 43, and thus, may enhance the stability of the processing process and may enhance the quality of a substrate on which the processing process is completed.

The measurement hole 52 may be formed to pass through a purge gas injecting body 430 included in the purge gas injecting module 43. The measurement mechanism 51 may be disposed on the purge gas injecting module 43. The measurement mechanism 51 may be disposed on the measurement hole 52 and may measure the temperature of the substrate 100 through the measurement hole 52.

The measurement hole 52 may be disposed to be apart from purge injecting holes 431 disposed in parallel along the diameter direction among a plurality of purge injecting holes 431 included in the purge gas injecting module 43 and to be parallel to the diameter direction. Although not shown, the measurement hole 52 may be disposed to be apart from the purge injecting holes 431 disposed in parallel along the diameter direction among the plurality of purge injecting holes 431 included in the purge gas injecting module 43 and to be inclined in a direction having a certain angle with respect to the diameter direction. Accordingly, the measurement hole 52 is disposed to decrease interference with the purge injecting holes 431 and is implemented so that the measurement mechanism 51 sequentially obtains temperature data of portions of the substrate 100 or portions of the substrate supporting unit 2 to obtain a total temperature distribution of the substrate 100. The injecting holes 431 disposed in parallel along the diameter direction denotes the purge injecting holes 431 disposed in the diameter line RL as illustrated in FIG. 10.

Although not shown, the measurement hole 52 may be formed in the lid 3. In this case, the measurement mechanism 51 may be disposed at a position, corresponding to the measurement hole 52, on the lid 3. The measurement hole 52 may be formed to pass through the lid 3. In this case, the measurement hole 52 may be formed at a portion, where the gas injecting unit 4 is not disposed, of the lid 3.

Although not shown, the substrate processing apparatus 1 according to the present inventive concept may include a transparent window which is disposed to plug the measurement hole 52. The measurement mechanism 51 may measure the temperature of the substrate 100 or the temperature of the substrate supporting unit 2 through the transparent window and the measurement hole 52. In a case where the processing process is performed in a state where an inner portion of the processing space is vacuum, the transparent window may be disposed to plug the measurement hole 52, and thus, may enable the inner portion of the processing space to be maintained in a vacuum state.

Referring to FIGS. 1 to 14, the substrate processing apparatus 1 according to the present inventive concept may include a detector 6.

The detector 6 detects the temperature distribution of the substrate 100 by using the temperature data obtained by the measurement mechanism 51. The temperature data obtained by the measurement mechanism 51 may include a point-based temperature of the substrate 100. The detector 6 may generate the total temperature distribution of the substrate 100 as a thermal image by using a plurality of temperature data obtained by the measurement mechanism 51. In the thermal image, the point-based temperature of the substrate 100 may be displayed in a color corresponding thereto. A color-based temperature may be implemented as a lookup table-type storage data and may be previously stored in the detector 6. When the measurement mechanism 51 measures the temperature of the substrate supporting unit 2 to obtain temperature data, the detector 6 may extract the temperature data of the substrate 100 from corresponding temperature data, and then, may detect the temperature distribution of the substrate 100 by using the extracted temperature data.

The detector 6 may include a generating module 61 and a conversion module 62.

The generating module 61 generates a noncircular detection image representing the temperature distribution of the substrate 100 by using the plurality of temperature data obtained by the measurement mechanism 51. The noncircular detection image may be implemented as a thermal image where the point-based temperature of the substrate 100 is expressed as a color. The generating module 61 may check the point-based temperature of the substrate 100 from the plurality of temperature data obtained by the measurement mechanism 51 and may match the point-based temperature of the substrate 100 with the storage data, thereby generating the noncircular detection image where the temperature distribution of the substrate 100 is expressed as a color. The noncircular detection image may be generated in a noncircular shape, and for example, as illustrated in FIG. 13, may be generated as an oval detection image. The reason that the noncircular detection image is generated despite the substrate 100 having a circular shape is because, in a process of rotating the substrate 100 with respect to the rotation shaft 2a, the measurement mechanism 51 measures the temperature of the substrate 100 or the temperature of the substrate supporting unit 2, and moreover, measures the temperature of the substrate 100 to obtain the temperature data at the measurement position which is apart from the diameter direction. The plurality of temperature data obtained by the measurement mechanism 51 may be provided to the generating module 61 through wired communication, wireless communication, etc.

The generating module 61 may generate the noncircular detection image representing a temperature distribution corresponding to one rotation of the substrate 100 by using a rotation speed of the substrate supporting unit 2 and a measurement time of the measurement mechanism 51 used to obtain the plurality of temperature data. Therefore, when the plurality of temperature data are obtained in a process where a plurality of substrates 100 are mounted on the substrate supporting unit 2 and rotate by 360 degrees with respect to the rotation shaft 2a a plurality of times, the generating module 61 may generate the noncircular detection image from pieces of temperature data, corresponding to a same number of rotations of the same substrate 100, among the plurality of temperature data.

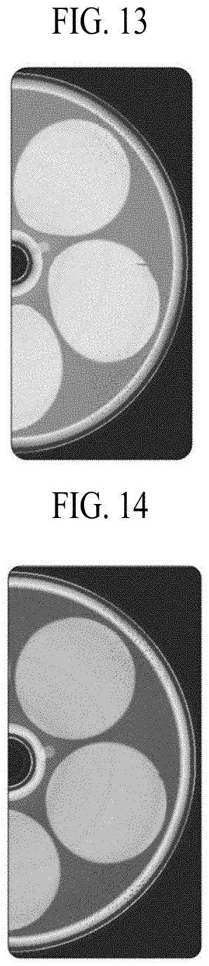

The conversion module 62 converts the noncircular detection image into a circular detection image corresponding to the substrate 100. For example, the converting module 62 may convert the noncircular detection image, illustrated in FIG. 13, into the circular detection image illustrated in FIG. 14. Therefore, a worker may check the temperature distribution of the substrate 100 by using a temperature distribution which is discriminatively displayed in a color in the circular detection image on the basis of a temperature. Accordingly, the substrate processing apparatus 1 according to the present inventive concept may provide the worker with the circular detection image corresponding to the substrate 100, thereby enhancing the easiness of an operation of checking the temperature distribution of the substrate 100. Although not shown, the conversion module 62 may provide the circular detection image to a display apparatus (not shown). Also, the noncircular detection image may be provided from the generating module 61 to the conversion module 62 through wired communication, wireless communication, etc.

In a process of converting the noncircular detection image into the circular detection image by using the conversion module 62, the conversion module 62 may consider an operation of measuring, by using the measurement mechanism 51, the temperature of the substrate 100 or the temperature of the substrate supporting unit 2 to obtain temperature data and an operation of measuring, by using the measurement mechanism 51, the temperature of the substrate 100 or the temperature of the substrate supporting unit 2 to obtain the temperature data at the measurement position apart from the diameter direction, in a process of rotating the substrate 100 with respect to the rotation shaft 2a.

To this end, the conversion module 62 may calculate point-based coordinates of the substrate 100 by using at least one of a rotation speed of the substrate supporting unit 2, a shortest separation distance SD, an inner included angle HA, an outer included angle OIA, and a middle included angle MIA, and then, may convert the noncircular detection image into the circular detection image on the basis of the calculated coordinates.

The shortest separation distance SD denotes a shortest distance among distances by which the measurement hole 52 is apart from the diameter direction. For example, the shortest separation distance SD may denote a distance by which the diameter line RL is rectilinearly apart from the measurement hole 52. The diameter line RL may denote a virtual line which extends in the diameter direction.

The inner included angle IIA denotes an included angle between an inner connection line IL and the diameter line RL. The inner connection line IL denotes a virtual connection line which connects an inner end 52a of the measurement hole 52 to the rotation shaft 2a. The inner end 52a denotes a portion of the measurement hole 52 facing the rotation shaft 2a. The inner connection line IL may be a virtual connection line which connects a middle point of the inner end 52a to the rotation shaft 2a, with respect to a direction parallel to the shortest separation distance SD.

The outer included angle OIA denotes an included angle between an outer connection line OL and the diameter line RL. The outer connection line OL denotes a virtual connection line which connects an outer end 52b of the measurement hole 52 to the rotation shaft 2a. The outer end 52b and the inner end 52a denote a portion of the measurement hole 52 facing each other. The outer connection line OL may be a virtual connection line which connects a middle point of the outer end 52b to the rotation shaft 2a, with respect to the direction parallel to the shortest separation distance SD.

The middle included angle MIA denotes an included angle between a middle connection line ML and the diameter line RL. The middle connection line ML denotes a virtual connection line which connects a middle end 52c of the measurement hole 52 to the rotation shaft 2a. The middle end 52c denotes a portion of the measurement hole 52, which is apart from each of the inner end 52a and the outer end 52b by the same distance. The middle connection line ML may be a virtual connection line which connects a middle point of the middle end 52c to the rotation shaft 2a, with respect to the direction parallel to the shortest separation distance SD.

As described above, the conversion module 62 may calculate the point-based coordinates of the substrate 100 by using at least one of the rotation speed of the substrate supporting unit 2, the shortest separation distance SD, the inner included angle HA, the outer included angle OIA, and the middle included angle MIA, and then, may convert the noncircular detection image into the circular detection image on the basis of the calculated coordinates. In this case, the point-based coordinates of the substrate 100 may correspond to absolute coordinates with respect to a real substrate 100. When the point-based coordinates of the substrate 100 are calculated, the conversion module 62 may move a point-based temperature of the substrate 100 on the basis of the absolute coordinates, and thus, may convert the noncircular detection image into the circular detection image.

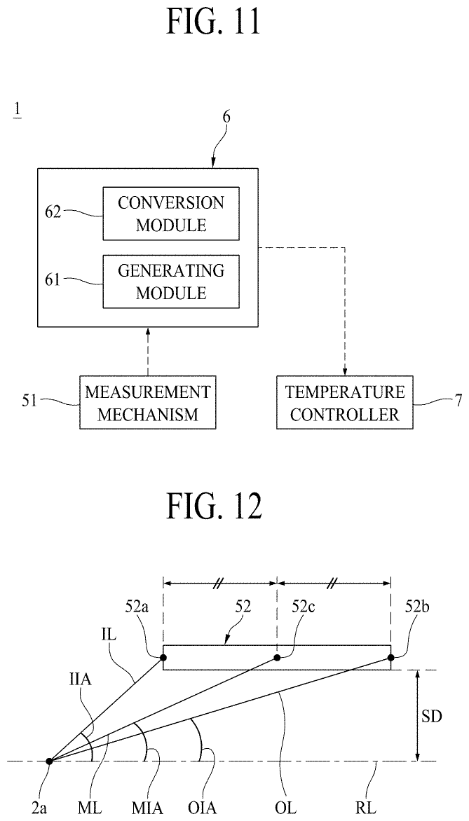

Referring to FIGS. 1 and 11, the substrate processing apparatus 1 according to the present inventive concept may be implemented so that the temperature distribution of the substrate 100 detected by the detector 6 is reflected in a process condition of the processing process. In this case, the substrate processing apparatus 1 according to the present inventive concept may include a temperature controller 7.

The temperature controller 7 controls a temperature of a substrate 100 mounted on the substrate supporting unit 2. The temperature controller 7 may control the temperature of the substrate supporting unit 2, and thus, may control the temperature of the substrate 100 through the substrate supporting unit 2. In this case, the temperature controller 7 may be installed in the substrate supporting unit 2. Although not shown, the temperature controller 7 may be implemented to control the temperature of the substrate 100 by using electricity. In this case, the temperature controller 7 may be implemented as an electric heater. Although not shown, the temperature controller 7 may be implemented to control the temperature of the substrate 100 by using a temperature control fluid. In this case, the temperature controller 7 may include a pipeline which is installed in the substrate supporting unit 2, a pump which provides the temperature control fluid to the pipeline, and a control unit which controls a temperature of the temperature control fluid provided to the pipeline by the pump.

The temperature controller 7 may control a temperature of a substrate 100, supported by the substrate supporting unit 2, to a predetermined processing temperature by using the temperature distribution of the substrate 100 detected by the detector 6. The predetermined processing temperature may vary based on the kind of the processing process, the kind of the substrate 100, and the kind of a thin film and may be previously set by a worker.

The gas injecting unit 4 may stop injecting of a gas to the substrate supporting unit 2 until the temperature of the substrate 100 supported by the substrate supporting unit 2 is controlled to the processing temperature by using the temperature distribution of the substrate 100 detected by the detector 6. When the temperature of the substrate 100 supported by the substrate supporting unit 2 is controlled to the processing temperature by using the temperature distribution of the substrate 100 detected by the detector 6, the gas injecting unit 4 may start to inject the gas to the substrate supporting unit 2. Accordingly, the substrate processing apparatus 1 according to the present inventive concept may enhance the uniformity of quality of a substrate on which a processing process is completed.

The present inventive concept described above are not limited to the above-described embodiments and the accompanying drawings and those skilled in the art will clearly appreciate that various modifications, deformations, and substitutions are possible without departing from the scope and spirit of the invention.

1. An apparatus for processing substrate, the apparatus comprising:
a chamber providing a processing space;
a lid covering an upper portion of the chamber;
a substrate supporting unit supporting at least one substrate and rotating about a rotation shaft;
a gas injecting unit disposed over a diameter direction with respect to the rotation shaft of the substrate supporting unit to inject a processing gas; and
a measurement unit measuring a temperature of a substrate supported by the substrate supporting unit or a temperature of the substrate supporting unit at a measurement position apart from the diameter direction,
wherein the measurement unit is disposed in parallel with the diameter direction or disposed to be inclined in a direction having a certain angle with respect to the diameter direction.

2. The apparatus of claim 1, wherein
the gas injecting unit comprises a purge gas injecting module injecting a purge gas, and
the measurement unit comprises a measurement mechanism disposed over the purge gas injecting module and a measurement hole formed in the purge gas injecting module.

3. The apparatus of claim 2,
wherein the purge gas injecting module comprises a plurality of purge injecting holes injecting the purge gas,
wherein the measurement hole is disposed to be apart from purge injecting holes disposed in parallel along the diameter direction among the plurality of purge injecting holes,
wherein the measurement hole is disposed in parallel with the diameter direction or disposed to be inclined in a direction having a certain angle with respect to the diameter direction.

4. The apparatus of claim 1, wherein the measurement unit comprises:
a measurement hole disposed at the measurement position apart from the diameter direction; and
a measurement mechanism measuring a temperature of a substrate passing through a region under the measurement hole or a temperature of the substrate supporting unit disposed under the measurement hole to obtain temperature data,
wherein the measurement hole is disposed in parallel with the diameter direction or disposed to be inclined in a direction having a certain angle with respect to the diameter direction.

5. The apparatus of claim 2, comprising a detector detecting a temperature distribution of a substrate by using temperature data obtained by the measurement mechanism,
wherein the detector comprises a generating module generating a noncircular detection image representing a temperature distribution of a substrate by using the temperature data and a conversion module converting the noncircular detection image into a circular detection image corresponding to the substrate.

6. The apparatus of claim 5,
wherein the conversion module calculates point-based coordinates of a substrate, and then converts the noncircular detection image into the circular detection image on the basis of the calculated coordinates,
wherein the conversion module calculates the point-based coordinates of a substrate by using at least one of a rotation speed of the substrate supporting unit, a shortest separation distance by which the measurement hole is apart from the diameter direction, an inner included angle between a inner connection line and a diameter line, an outer included angle between a outer connection line and the diameter line, and a middle included angle between a middle connection line and the diameter line,
wherein the inner connection line is a virtual connection line which connects an inner end of the measurement hole to the rotation shaft,
wherein the diameter line is a virtual line which extends in the diameter direction,
wherein the outer connection line is a virtual connection line which connects an outer end of the measurement hole to the rotation shaft,
wherein the middle connection line is a virtual connection line which connects a middle end to the rotation shaft, the middle end is a portion which is apart from each of the inner end of the measurement hole and the outer end of the measurement hole by the same distance.

7. The apparatus of claim 4, wherein
the gas injecting unit comprises a plurality of injecting modules injecting the processing gas, and
the measurement hole is formed in at least one of the plurality of injecting modules.

8. The apparatus of claim 4, wherein the measurement hole is formed in the lid.

9. An injecting module of an apparatus for processing substrate, the injecting module comprising:
an injecting hole for injecting a processing gas into a chamber where a processing process is performed on a substrate;
an injecting body where the injecting hole is formed in plurality; and
a measurement hole formed to pass through the injecting body at a position apart from the plurality of injecting holes,
wherein
some injecting holes among the plurality of injecting holes are disposed in a diameter direction with respect to a rotation shaft of a substrate supporting part which rotates in a state where the substrate supporting part supports a substrate, in the chamber, and
the measurement hole is disposed to be apart from injecting holes disposed in parallel along the diameter direction and to be inclined in a direction which is parallel to the diameter direction or has a certain angle with respect to the diameter direction.

10. The injecting module of claim 9,
wherein the measurement hole is formed at a position apart from each of one side of the injecting body and the other side of the injecting body with respect to a direction in which a substrate supported by the substrate supporting unit rotates about the rotation shaft,
wherein the measurement hole is apart from each of one side of the injecting body and the other side of the injecting body by different distances.

11. The apparatus of claim 4, comprising a detector detecting a temperature distribution of a substrate by using temperature data obtained by the measurement mechanism,
wherein the detector comprises a generating module generating a noncircular detection image representing a temperature distribution of a substrate by using the temperature data and a conversion module converting the noncircular detection image into a circular detection image corresponding to the substrate.

12. The apparatus of claim 11,
wherein the conversion module calculates point-based coordinates of a substrate, and then converts the noncircular detection image into the circular detection image on the basis of the calculated coordinates,
wherein the conversion module calculates the point-based coordinates of a substrate by using at least one of a rotation speed of the substrate supporting unit, a shortest separation distance by which the measurement hole is apart from the diameter direction, an inner included angle between a inner connection line and a diameter line, an outer included angle between a outer connection line and the diameter line, and a middle included angle between a middle connection line and the diameter line,
wherein the inner connection line is a virtual connection line which connects an inner end of the measurement hole to the rotation shaft,
wherein the diameter line is a virtual line which extends in the diameter direction,
wherein the outer connection line is a virtual connection line which connects an outer end of the measurement hole to the rotation shaft,
wherein the middle connection line is a virtual connection line which connects a middle end to the rotation shaft, the middle end is a portion which is apart from each of the inner end of the measurement hole and the outer end of the measurement hole by the same distance.
